(19) United States
(12) Patent Application Publication
(10) Pub. No.: US 2007/0256635 A1
(43) Pub. Date: Nov. 8, 2007

(54) UV activation of NH3 for III-N deposition

(75) Inventors: David Bour, Cupertino, CA (US); Lori Washington, Union City, CA (US); Sandeep Nijhawan, Los Altos, CA (US); Ronald Stevens, San Ramon, CA (US); Jacob Smith, Santa Clara, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc. A Delaware corporation, Santa Clara, CA (US)

(21) Appl. No.: 11/416,333

(22) Filed: May 2, 2006

(51) Int. Cl. C23C 16/00

(52) U.S. Cl. 118/715

(57) ABSTRACT

Systems are disclosed for fabricating compound nitride semiconductor structures. The systems include a housing defining a processing chamber, a substrate holder disposed within the processing chamber, an NH₃ source, a group-III precursor source, an ultraviolet source, and a CVD showerhead disposed over the substrate holder. The showerhead has a first plenum fluidicly coupled with the NH₃ source, with the first plenum having channels fluidicly coupled with an interior of the processing chamber. The first plenum is optically coupled with the ultraviolet light source at an ultraviolet wavelength to receive light transmitted by the ultraviolet light source within the first plenum. The CVD showerhead also has a second plenum fluidicly coupled with the group-III precursor source, with the second plenum having channels fluidicly coupled with the interior of the processing chamber.

### BACKGROUND OF THE INVENTION

The history of light-emitting diodes (“LEDs”) is sometimes characterized as a “crawl up the spectrum.” This is because the first commercial LEDs produced light in the infrared portion of the spectrum, followed by the development of red LEDs that used GaAsP on a GaAs substrate. This was, in turn, followed by the use of GaP LEDs with improved efficiency that permitted the production of both brighter red LEDs and orange LEDs. Refinements in the use of GaP then permitted the development of green LEDs, with dual GaP chips (one in red and one in green) permitting the generation of yellow light. Further improvements in efficiency in this portion of the spectrum were later enabled through the use of GaAlAsP and InGaAlP materials.

This evolution towards the production of LEDs that provide light at progressively shorter wavelengths has generally been desirable not only for its ability to provide broad spectral coverage but because diode production of short-wavelength light may improve the information storage capacity of optical devices like CD-ROMs. The production of LEDs in the blue, violet, and ultraviolet portions of the spectrum was largely enabled by the development of nitride-based LEDs, particularly through the use of GaN. While some modestly successful efforts had previously been made in the production of blue LEDs using SiC materials, such devices suffered from poor luminescence as a consequence of the fact that their electronic structure has an indirect bandgap.

While the feasibility of using GaN to create photoluminescence in the blue region of the spectrum has been known for decades, there were numerous barriers that impeded their practical fabrication. These included the lack of a suitable substrate on which to grow the GaN structures, generally high thermal requirements for growing GaN that resulted in various thermal-convection problems, and a variety of difficulties in efficient p-doping such materials. The use of sapphire as a substrate was not completely satisfactory because it provides approximately a 15% lattice mismatch with the GaN. Progress has subsequently been made in addressing many aspects of these barriers. For example, the use of a buffer layer of AlN or GaN formed from a metalorganic vapor has been found effective in accommodating the lattice mismatch. Further refinements in the production of Ga-N-based structures has included the use of AlGaN materials to form heterojunctions with GaN and particularly the use of InGaN, which causes the creation of defects that act as quantum wells to emit light efficiently at short wavelengths. Indium-rich regions have a smaller bandgap than surrounding material, and may be distributed throughout the material to provide efficient emission centers.

While some improvements have thus been made in the manufacture of such compound nitride semiconductor devices, it is widely recognized that a number of deficiencies yet exist in current manufacturing processes. Moreover, the high utility of devices that generate light at such wavelengths has caused the production of such devices to be an area of intense interest and activity. In view of these considerations, there is a general need in the art for improved methods and systems for fabricating compound nitride semiconductor devices.

### BRIEF SUMMARY OF THE INVENTION

Embodiments of the invention provide systems for fabricating compound nitride semiconductor structures. Each of various embodiments include a housing defining a processing chamber, a substrate holder disposed within the processing chamber, an NH₃ source, a group-III precursor source, and an ultraviolet source. In a first set of embodiments, the system also includes a CVD showerhead disposed over the substrate holder. The showerhead comprises a first plenum fluidicly coupled with the NH₃ source. The first plenum has a plurality of first channels fluidicly coupled with an interior of the processing chamber. The first plenum is optically coupled with the ultraviolet light source at an ultraviolet wavelength to receive light transmitted by the ultraviolet light source within the first plenum. The CVD showerhead also comprises a second plenum fluidicly coupled with the group-III precursor source. The second plenum has a plurality of second channels fluidicly coupled with the interior of the processing chamber.

In some of these embodiments, the ultraviolet wavelength is an NH₃ absorption wavelength, with the ultraviolet light source either comprising a substantially monotonic light source having a wavelength substantially equal to the ultraviolet wavelength or transmitting light over a wavelength band that includes the ultraviolet wavelength. The group-III precursor source may comprise a gallium source. In some instances, the group-III precursor source comprises a plurality of distinct group-III elements.

The first plenum may comprise a window transmissive at the ultraviolet wavelength, with the ultraviolet source disposed relative to the window to transmit light into the first plenum. Examples of materials that may be comprised by the window include quartz and sapphire.

Alternatively, the system may additionally comprise an optical conduit transmissive at the ultraviolet wavelength. The optical conduit traverses at least a portion of the first plenum and is optically coupled with the ultraviolet light source to couple light from the ultraviolet light source into the first plenum. Examples of materials that may be comprised by the optical conduit include quartz and sapphire. The optical conduit may have a roughened outer surface. In one embodiment, the optical conduit comprises a plurality of optical fibers.

In a second set of embodiments, the system also includes a CVD showerhead disposed over the substrate holder. The CVD showerhead comprises first and second plenums. The first plenum is fluidicly coupled with the NH₃ source and has a plurality of first channels fluidicly coupled with an interior of the processing chamber. The second plenum is fluidicly coupled with the group-III precursor source and has a plurality of second channels fluidicly coupled with the interior of the processing chamber. In these embodiments, the system additionally comprises an optical conduit optically coupled with the ultraviolet source. The optical conduit traverses through the CVD showerhead to transmit light from the ultraviolet light source onto a surface of a substrate disposed over the substrate holder.

The optical conduit may sometimes comprise quartz or sapphire. In certain embodiments, the optical conduit comprises a plurality of optical fibers. Each optical fiber is optically coupled with the ultraviolet light source and traverses through the CVD showerhead to transmit light from the ultraviolet light source onto the surface of the substrate. In different embodiments, at least one of the optical fibers passes through one of the first channels or at least one of the optical fibers passes through one of the second channels.

In a third set of embodiments, the system includes a CVD showerhead disposed over the substrate holder. In these embodiments, the CVD showerhead comprises a first plurality of tubes and a second plurality of tubes. Each of the first plurality of tubes has substantially concentric inner and outer channels. The inner channel is fluidicly coupled with the group-III precursor source and the outer channel is adapted for carrying a coolant flow. Each of the second plurality of tubes is fluidicly coupled with the NH₃ source and is optically coupled with the ultraviolet source.

In one embodiment, the coolant flow comprises a water flow. An interior surface of at least one of the second plurality of tubes may be roughened and/or may comprise an ultraviolet coating. In one embodiment, at least one of the second plurality of tubes comprises an optical lightguide optically coupled with the ultraviolet light source and disposed within an interior of the at least one of the second plurality of tubes.

In a fourth set of embodiments, the system comprises a crossflow channel. The crossflow comprises a material transmissive to an ultraviolet wavelength and comprises a separation plate to define a plurality of subchannels. A first of the subchannels is fluidicly coupled with the group-III precursor source and is configured to provide a flow of a group-III precursor over a substrate disposed over the substrate holder in a direction substantially parallel to a surface of the substrate. A second of the subchannels is fluidicly coupled with the NH₃ source and configured to provide a flow of NH₃ over the substrate in a direction substantially parallel to the surface of the substrate. The ultraviolet light source is in optical communication with the crossflow channel and configured to transmit light at the ultraviolet wavelength through the material to activate the NH₃.

In some of these embodiments, the ultraviolet light source is configured to transmit light through the material at a position along the crossflow channel before termination of the separation plate into the second of the subchannels. In others of these embodiments, the ultraviolet light source is configured to transmit light through the material at a position along the crossflow channel after termination of the separation plate where the group-III precursor and the NH₃ mix. For instance, the position may be over the substrate holder. The separation plate may comprise an ultraviolet reflective coating on a side defining the second of the subchannels.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 provides a schematic illustration of a structure of a GaN-based LED;

FIG. 2 is a simplified representation of an exemplary CVD apparatus that may be used in implementing certain embodiments of the invention;

FIG. 3 is a flow diagram summarizing methods of using ultraviolet activation of NH₃ in embodiments of the invention;

FIG. 4 is a schematic illustration of one structural arrangement that may be used to apply ultraviolet light for activation of NH₃;

FIG. 5 is a schematic illustration of another structural arrangement that may be used to apply ultraviolet light for activation of NH₃;

FIG. 6 is a schematic illustration of a further structural arrangement that may be used to apply ultraviolet light for activation of NH₃;

FIGS. 7A and 7B are schematic illustrations of techniques for activation of NH₃ with ultraviolet light in cross-flow reactors; and

FIGS. 8A-8D are schematic illustrations of a showerhead structure that may be used in various embodiments of the invention.

### DETAILED DESCRIPTION OF THE INVENTION

1. Overview

One class of techniques for deposition of group-III nitride structures is metalorganic chemical vapor deposition (“MOCVD”). Such techniques achieve deposition by providing flows of precursors for both the group-III element(s) and nitrogen to a processing chamber where thermal processes act to achieve growth of a III-N film. The effectiveness of the growth may depend on a wide array of different factors, notably including the rate at which precursors are flowed into the processing chamber and the environmental conditions within the processing chamber. Particularly relevant to effective deposition of III-N films is the temperature within the processing chamber, although other conditions such as the pressure are also relevant.

The most common nitrogen precursor used in such processes is NH₃, which is a very stable molecule that is difficult to pyrolyze thermally. The deposition process requires that the NH₃ dissociate to make activated nitrogen available for reaction in growing the film. The difficulty of pyrolyzing NH₃ is accommodated in a number of ways that generally reflect otherwise undesirable processing conditions. For example, because dissociation rates are relatively low, very large flows of NH₃ are typically needed to provide sufficient activated nitrogen for reaction, resulting in large consumption rates. In addition, processing temperatures are also somewhat elevated in part to provide an environment that increases the dissociation rate. Deposition of III-N films is typically performed at temperatures that exceed 1000° C. But the use of very high temperatures exacerbates difficulties that result from differences in thermal expansion between the nitride film and the substrate over which it is deposited. These differences in thermal expansion are manifested by a distortion in the shape of the structure when the substrate is cooled, either as part of a multistep process or at completion of a process for fabricating a specific structure. Such distortions may result in wavelength and light-output variations for devices formed across the structure.

In addition, the inventors have recognized that relatively low dissociation rate of NH₃ has a generally detrimental effect on the optoelectronic properties of the III-N film that is deposited. This may be understood in the context of the chemistry that governs defect formation in nitride structures. The inventors believe that nitrogen vacancies in III-N films are nonradiative, a hypothesis that results from analogy with vacancies in other III-V semiconductor structures in which the group-V vacancies are known to be nonradiative. The difficulty of pyrolyzing NH₃ results in relative fewer nitrogen vacancies being formed in the deposited film, which in turn causes the overall internal quantum efficiency of the deposited film to be around 40-50%. The inventors anticipate that a mechanism for increasing the overall dissociation rate of NH₃ will reduce the number of nitrogen vacancies formed by providing more activated nitrogen for reaction and thereby increase the internal quantum efficiency, perhaps to about 80-90%. This hypothesis is consistent with observations that improved optoelectronic properties are obtained in processes performed at higher NH₃ partial pressures.

An increase in NH₃ dissociation is achieved in embodiments of the invention by using ultraviolet light for activation, in addition to pyrolysis mechanisms. The improved activation permits a reduction in flow rates of NH₃ that results in corresponding reduction in overall NH₃ consumption, permits a reduction in processing temperature that mitigates the shape distortions that arise from thermal-expansion differences, permits an increase in overall film growth rates, and/or permits the fabrication of films having improved optoelectronic properties. Different embodiments of the invention may use substantially monochromatic light that match the NH₃ absorption wavelength or may use a band of light that includes the NH₃ absorption wavelength. Use of substantially monochromatic light is generally more efficient.

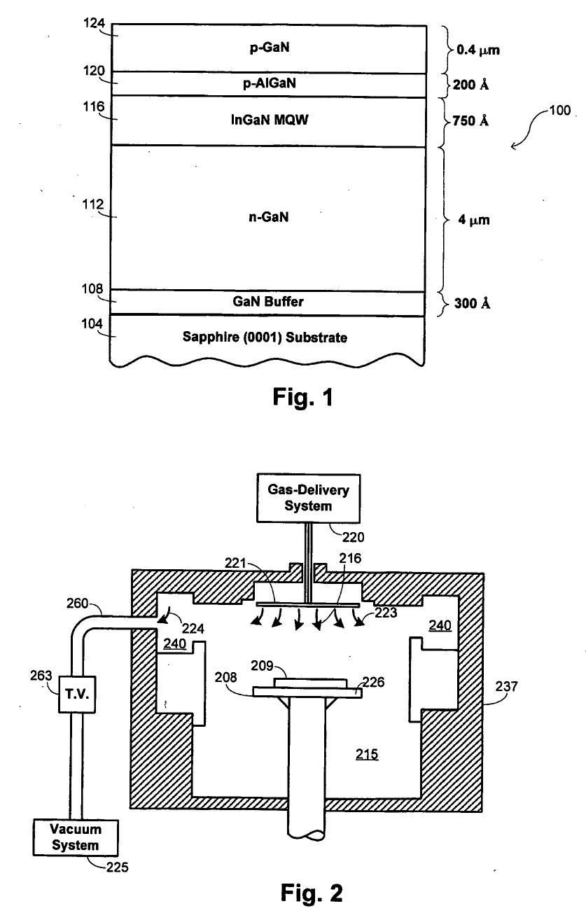

One typical nitride-based structure is illustrated in FIG. 1 as a GaN-based LED structure 100. It is fabricated over a sapphire (0001) substrate 104. An n-type GaN layer 112 is deposited over a GaN buffer layer 108 formed over the substrate. An active region of the device is embodied in a multi-quantum-well layer 116, shown in the drawing to comprise an InGaN layer. A pn junction is formed with an overlying p-type AlGaN layer 120, with a p-type GaN layer 124 acting as a contact layer.

2. Exemplary Substrate Processing System

FIG. 2 is a simplified diagram of an exemplary chemical vapor deposition (“CVD”) system, illustrating the basic structure of a chamber in which individual deposition steps can be performed. This system is suitable for performing thermal, sub-atmospheric CVD (“SACVD”) processes, as well as other processes, such as reflow, drive-in, cleaning, etching, deposition, and gettering processes. In some instances multiple-step processes can still be performed within an individual chamber before removal for transfer to another chamber. The major components of the system include, among others, a vacuum chamber 215 that receives process and other gases from a gas delivery system 220, a vacuum system 225, and a control system (not shown). These and other components are described in more detail below. While the drawing shows the structure of only a single chamber for purposes of illustration, it will be appreciated that multiple chambers with similar structures may be provided as part of a cluster tool, each tailored to perform different aspects of certain overall fabrication processes.

The CVD apparatus includes an enclosure assembly 237 that forms vacuum chamber 215 with a gas reaction area 216. A gas distribution structure 221 disperses reactive gases and other gases, such as purge gases, toward one or more substrates 209 held in position by a substrate support structure 208. Between gas distribution structure 221 and the substrate 209 is gas reaction area 216. Heaters 226 can be controllably moved between different positions to accommodate different deposition processes as well as for an etch or cleaning process. A center board (not shown) includes sensors for providing information on the position of the substrate.

Different structures may be used for heaters 226. For instance, some embodiments of the invention advantageously use a pair of plates in close proximity and disposed on opposite sides of the substrate support structure 208 to provide separate heating sources for the opposite sides of one or more substrates 209. Merely by way of example, the plates may comprise graphite or SiC in certain specific embodiments. In another instance, the heaters 226 include an electrically resistive heating element (not shown) enclosed in a ceramic. The ceramic protects the heating element from potentially corrosive chamber environments and allows the heater to attain temperatures up to about 1200° C. In an exemplary embodiment, all surfaces of heaters 226 exposed to vacuum chamber 215 are made of a ceramic material, such as aluminum oxide (Al₂O₃ or alumina) or aluminum nitride. In another embodiment, the heaters 226 comprises lamp heaters. Alternatively, a bare metal filament heating element, constructed of a refractory metal such as tungsten, rhenium, iridium, thorium, or their alloys, may be used to heat the substrate. Such lamp heater arrangements are able to achieve temperatures greater than 1200° C., which may be useful for certain specific applications.

Reactive and carrier gases are supplied from gas delivery system 220 through supply lines to the gas distribution structure 221. In some instances, the supply lines may deliver gases into a gas mixing box to mix the gases before delivery to the gas distribution structure. In other instances, the supply lines may deliver gases to the gas distribution structure separately, such as in certain showerhead configurations described below. Gas delivery system 220 includes a variety of gas sources and appropriate supply lines to deliver a selected amount of each source to chamber 215 as would be understood by a person of skill in the art. Generally, supply lines for each of the gases include shut-off valves that can be used to automatically or manually shut-off the flow of the gas into its associated line, and mass flow controllers or other types of controllers that measure the flow of gas or liquid through the supply lines. Depending on the process run by the system, some of the sources may actually be liquid sources rather than gases. When liquid sources are used, gas delivery system includes a liquid injection system or other appropriate mechanism (e.g., a bubbler) to vaporize the liquid. Vapor from the liquids is then usually mixed with a carrier gas as would be understood by a person of skill in the art. During deposition processing, gas supplied to the gas distribution structure 221 is vented toward the substrate surface (as indicated by arrows 223), where it may be uniformly distributed radially across the substrate surface in a laminar flow.

Purging gas may be delivered into the vacuum chamber 215 from gas distribution structure 221 and/or from inlet ports or tubes (not shown) through the bottom wall of enclosure assembly 237. Purge gas introduced from the bottom of chamber 215 flows upward from the inlet port past the heater 226 and to an annular pumping channel 240. Vacuum system 225 which includes a vacuum pump (not shown), exhausts the gas (as indicated by arrows 224) through an exhaust line 260. The rate at which exhaust gases and entrained particles are drawn from the annular pumping channel 240 through the exhaust line 260 is controlled by a throttle valve system 263.

The temperature of the walls of deposition chamber 215 and surrounding structures, such as the exhaust passageway, may be further controlled by circulating a heat-exchange liquid through channels (not shown) in the walls of the chamber. The heat-exchange liquid can be used to heat or cool the chamber walls depending on the desired effect. For example, hot liquid may help maintain an even thermal gradient during a thermal deposition process, whereas a cool liquid may be used to remove heat from the system during other processes, or to limit formation of deposition products on the walls of the chamber. Gas distribution manifold 221 also has heat exchanging passages (not shown). Typical heat-exchange fluids water-based ethylene glycol mixtures, oil-based thermal transfer fluids, or similar fluids. This heating, referred to as heating by the “heat exchanger”, beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

The system controller controls activities and operating parameters of the deposition system. The system controller may include a computer processor and a computer-readable memory coupled to the processor. The processor executes system control software, such as a computer program stored in memory. The processor operates according to system control software (program), which includes computer instructions that dictate the timing, mixture of gases, chamber pressure, chamber temperature, microwave power levels, pedestal position, and other parameters of a particular process. Control of these and other parameters is effected over control lines that communicatively couple the system controller to the heater, throttle valve, and the various valves and mass flow controllers associated with gas delivery system 220.

3. Exemplary Embodiments

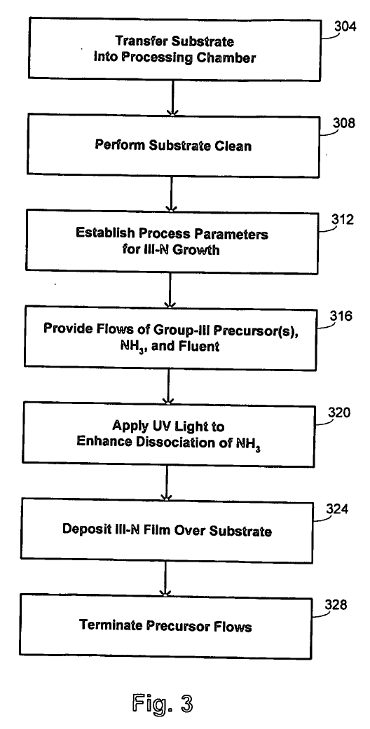

An overview of embodiments of the invention is illustrated with the flow diagram of FIG. 3, which summarizes methods for fabricating a compound nitride semiconductor structure. The method begins at block 304 with a substrate being transferred into a processing chamber. Suitable substrate materials over which nitride structures may be fabricated include sapphire, SiC, Si, spinel, lithium gallate, ZnO, and others. The substrate is cleaned at block 308, after which process parameters suitable for growth of a nitride layer may be established at block 312. Such process parameters may include temperature, pressure, and the like to define an environment within the processing chamber appropriate for thermal deposition of a nitride layer. Flows of precursors are provided to the processing chamber at block 316 to enable growth of structures that comprise a group-III element and nitrogen, referred to herein as “III-N” structures. The source of nitrogen is provided with a flow of NH₃ and suitable group-III precursors include trimethyl gallium (“TMG”) when the group-III element comprises Ga, trimethyl aluminum (“TMA”) when the group-III element comprises Al, and trimethyl indium (“TMI”) when the group-III element comprises In. In some instances, the group-III element may comprise a plurality of group-III elements, such as where flows of both TMG and TMA are provided to deposit an AlGaN layer, where flows of both TMG and TMI are provided to deposit an InGaN layer, or where flows of TMG, TMA, and TMI are provided to deposit a quaternary AlInGaN layer. The relative stoichiometry of the different group-III elements in the deposited film may be determined by relative flow rates of the corresponding precursors. The flows provided at block 316 also include a fluent gas that acts as a carrier for the precursors. Typical carrier gases that are used include N₂ and/or H₂.

In some instances, additional group-V precursors may also be included in the flows at block 316. For example, a III-N-P structure may be fabricated by including a flow of phosphine PH₃ or a III-N-As structure may be fabricated by including a flow of arsine AsH₃. The relative stoichiometry of the nitrogen to the other group-V element in the deposited structure may be determined by suitable choices of relative flow rates of the respective precursors. In still other instances, doped compound nitride structures may be formed by including dopant precursors, particular examples of which include the use of rare-earth dopants.

The processing conditions established at blocks 312 and the precursor flows provided at block 316 may vary depending on specific applications. The following table provides exemplary processing conditions and precursor flow rates that are generally suitable in the growth of nitride semiconductor structures using the devices described above:

| | |
|---|---|
| Parameter | Value |

| | | |
|---|---|---|
| Temperature | (° C.) | 500-1500 |
| Pressure | (torr) | 50-1000 |
| TMG flow | (sccm) | 0-50 |
| TMA flow | (sccm) | 0-50 |
| TMI flow | (sccm) | 0-50 |
| PH₃ flow | (sccm) | 0-1000 |
| AsH₃ flow | (sccm) | 0-1000 |
| NH₃ flow | (sccm) | 100-100,000 |
| N₂ flow | (sccm) | 0-100,000 |
| H₂ flow | (sccm) | 0-100,000 |

As will be evident from the preceding description, a process might not use flows of all the precursors identified in the table in any given process.

Dissociation of the NH₃ is promoted through application of ultraviolet light at block 320. As noted above, such application permits the overall flow rate of NH₃ to be provided in the lower portion of the cited range so that in some embodiments, the NH₃ flow rate is less than 10,000 sccm, is less than 5000 sccm, is less than 2000 sccm, is less than 1000 sccm, is less than 500 sccm, or is less than 200 sccm. The application of ultraviolet light also permits more effective use of temperatures in the lower portion of the cited fange, with the temperature being less that 1000° C. in some embodiments. The overall growth rates when using such a process with application of ultraviolet light may exceed 3 μm/h, may exceed 4 μm/h, may exceed 5 μm/h, may exceed 6 μm/h, may exceed 7 μm/h, or may exceed 8 μm/h. In some embodiments, the ultraviolet activation is performed upstream of the substrate, while in other embodiments, a surface of the substrate is illuminated in performing the ultraviolet activation. Examples of structures that permit each of these types of activation are provided below.

Deposition of the III-N film at block 324 is thus achieved through the combination of providing suitable precursor flows under suitable processing conditions with ultraviolet activation of NH₃. Once the film has been deposited, the precursor flows are terminated at block 328. In some instances, this may be followed by further processing on the substrate, such as by depositing additional nitride or other layers. Such additional processing steps may be performed within the same processing chamber or the substrate may be transferred to a second processing chamber for further processing. When processing is performed in multiple chambers, further increases in productivity may result from performing specific processes in chambers adapted for efficient performance of those processes. Further description of a cluster tool that includes multiple chambers that may be used for such multichamber processes is described in copending, commonly assigned U.S. patent application Ser. No. ______, entitled “EPITAXIAL GROWTH OF COMPOUND NITRIDE SEMICONDUCTOR STRUCTURES,” filed by Sandeep Nijhawan et al. (Attorney Docket No. A 10938/T68100), the entire disclosure of which is incorporated herein by reference for all purposes.

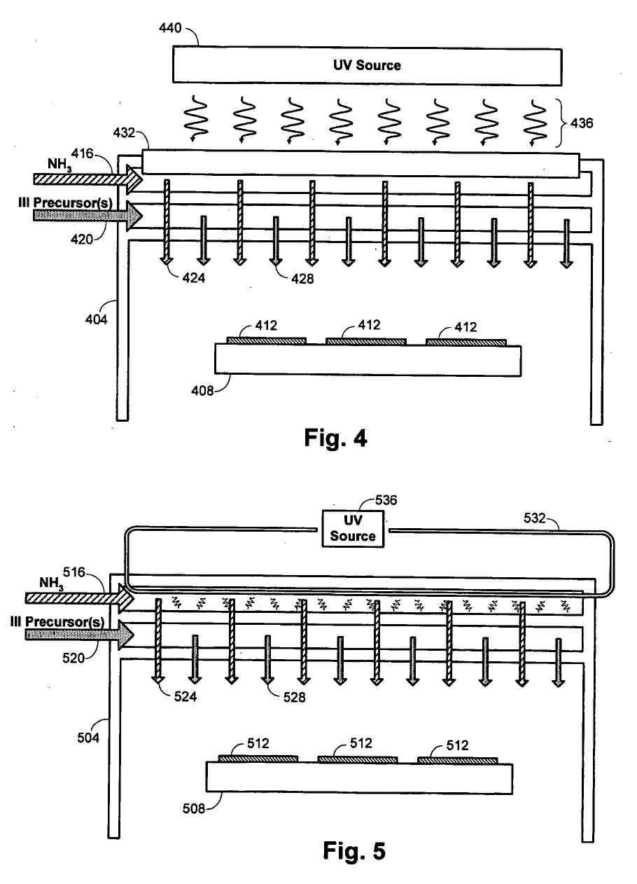

One exemplary structure that may be used to provide ultraviolet activation of NH₃ is shown in FIG. 4. This structure provides a processing chamber 404 in which a substrate 412 may be disposed on a substrate support 408. The drawing illustrates that in some instances multisubstrate processing may be performed by having a plurality of substrates disposed within the processing chamber 404. Precursors are provided to the processing chamber using a showerhead structure. Such showerhead structures function generally by providing different precursors to different plenums that have separate distribution conduits to the interior of the processing chamber. In this example, the group-III precursor(s) 420 are provided to a lower plenum and the NH₃ 416 is provided to an upper plenum, the two plenums having interleaved distribution conduits over the substrate support 408 to provide NH₃ flows 424 and group-III-precursor flows 428 into the processing chamber 404.

A window 432 that is at least partially transparent to ultraviolet light is provided to the plenum through which the NH₃ is provided. Ultraviolet light 436 is generated by an ultraviolet source 440 and transmitted through the window to activate the NH₃. The NH₃ is thus excited into an active state before injection into the processing chamber 404. Examples of suitable window materials include sapphire and quartz, although other materials that are at least partially transmissive at ultraviolet wavelengths may alternatively be used. The ultraviolet source 440 may be substantially monochromatic at the activation wavelength of NH₃ or may provide a wavelength band that includes the activation wavelength.

FIG. 5 illustrates a variation that may be used with a showerhead arrangement, with optical fibers running through the plenum used for NH₃ distribution to provide a propagation conduit for delivery of the ultraviolet light. In this illustration, the processing chamber 504 again housing a substrate support 508 for one or more substrates 512. One or more group-III precursors 520 are provided to a first plenum in the showerhead that delivers flows 528 of the group-III precursor to the processing chamber 504 over the substrate(s) 512. These flows are interleaved with flows 524 of activated NH₃ from a second plenum in the showerhead that receives a flow of NH₃. Activation within the second plenum is achieved by providing ultraviolet light from an ultraviolet source 536 through one or more optical fibers 532 that pass through the second plenum. Like the arrangement of FIG. 4, this arrangement provides an illustration of an embodiment in which the NH₃ is activated before injection into the processing chamber 504.

The optical fiber(s) 532 are made of a material transmissive at ultraviolet wavelengths, such as sapphire. In certain embodiments, the outer surface of the optical fiber(s) is roughened to improve scattering of the ultraviolet light out of the fiber(s) and into the second plenum. Different mechanisms for propagating light through the optical fiber(s) may be used. For instance, in many embodiments, propagation is unidirectional, with the ultraviolet source 536 being provided at one end of the fiber(s). In other instances, propagation may be bidirectional through the fiber(s) with a light source being provided at each end of the fiber(s). One such arrangement is illustrated in FIG. 5 where the fiber 532 is configured to have each of its two endpoints proximate a single ultraviolet source 536; in other embodiments, multiple ultraviolet sources may be used so that different ultraviolet sources are proximate different ends of the fiber(s) 532.

Because light is provided to the second plenum through fibers passing through the plenum, there is greater flexibility in which plenum is to be used for particular precursors. In particular, while the illustration of FIG. 5 shows the second plenum to be the top plenum, similar to FIG. 4, this is not a requirement and the second plenum could alternatively be the lower plenum.

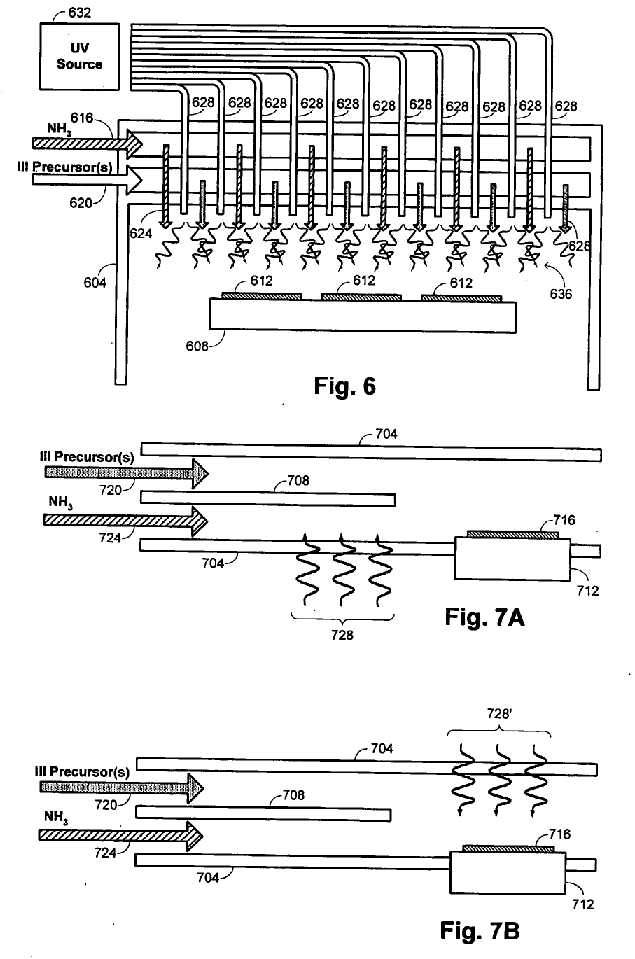

Another arrangement that uses optical fibers with a showerhead is illustrated in FIG. 6. The basic structure is similar to that of FIGS. 4 and 5: one or more substrates 612 are disposed over a substrate support 608 in a processing chamber 604 which receives flows of NH₃ 624 and one or more group-III precursors 628 from respective plenums of a showerhead. The plenums themselves separately receive flows of NH₃ 616 and the group-III precursor(s) 620. A plurality of light pipes 628 are provided to illuminate a surface of a substrate 612 disposed within the processing chamber 604 using light supplied by an ultraviolet source 632. The light pipes 628 may conveniently penetrate the showerhead structure to provide light 636 incident on the substrate surface. In the illustrated embodiment, the light pipes 628 pass between the showerhead precursor channels, but in other embodiments some or all of the light pipes 628 may pass through the precursor channels themselves. For instance, in one exemplary embodiment, each channel from the NH₃ plenum of the showerhead structure may include a light pipe 628, while in another exemplary embodiment, each channel from the group-III plenum includes a light pipe. A suitable material for the light pipes is sapphire, although other materials may be used in different embodiments.

Illumination with ultraviolet light incident on the substrate surface generally provides greater NH₃ activity than upstream excitation as achieved with the arrangements of FIGS. 4 and 5. This is a consequence of the fact that excitation then occurs directly on the deposition surface, providing less opportunity for relaxation and/or recombination to occur. Similar to the structure of FIG. 5, the embodiment of FIG. 6 is not constrained by relative configurations of the plenums—although FIG. 6 shows the flow of NH₃ 616 being received by the upper plenum and the flow of group-III precursor(s) 620 being received by the lower plenum, this arrangement may be reversed with no adverse effect on performance.

Illustrations of configurations that may be used for ultraviolet activation with a crossflow reactor are shown in FIGS. 7A and 7B. A crossflow reactor is one in which precursor flows are provided along flow channels in a direction approximately parallel to the substrate surface. The precursor flows may be provided along separate channels and permitted to mix in a region near the substrate. Thus, each of FIGS. 7A and 7B schematically illustrate an arrangement in which a substrate 716 is supported by a substrate support 712 within a processing chamber. A crossflow channel 704 includes a separation plate 708 that defines a plurality of separated subchannels for separate receipt of an NH₃ flow 724 and of a group-III precursor flow 720.

The crossflow channel 704 is fabricated of a material transmissive at ultraviolet wavelengths, such as sapphire or quartz, permitting illumination with ultraviolet light 728 or 728′through the channel 704 by an ultraviolet source (not shown). Illumination may take place at a positions along the channel 704 before termination of the separation plate 708 on the side of the NH₃ subchannel as indicated in FIG. 7A. This provides upstream activation and may notably be achieved irrespective of the relative positions of the NH₃ and group-III subchannels. While the drawing shows the NH₃ channel being the lower channel and closer to the substrate position, the upper channel could be used as the NH₃ channel, with illumination 728 being provided from the top of the structure.

In arrangements where the illumination takes place before termination of the separation plate 708, it may be advantageous for the surface of the separation plate to be coated with an ultraviolet reflector, at least on the subchannel side to be used for NH₃ flow. This permits more efficient activation by providing a double-pass for the ultraviolet light. Suitable coating materials include refractory metals like molybdenum, niobium, tantalum, rhenium, or tungsten, or may include a dielectric stack reflector.

Excitation at the substrate surface similar to that described in connection with FIG. 6 may be achieved by transmitting ultraviolet light 728′through the crossflow channel 704 at a point past termination of the separation plate 708, as shown in FIG. 7B. Again, such a technique is not limited by which of the subchannels is used for NH₃ flow and which is used for group-III precursor flow. Although FIG. 7B shows the top subchannel being used for group-III precursor flow and the lower subchannel being used for NH₃ flow, this assignment may be reversed in other embodiments.

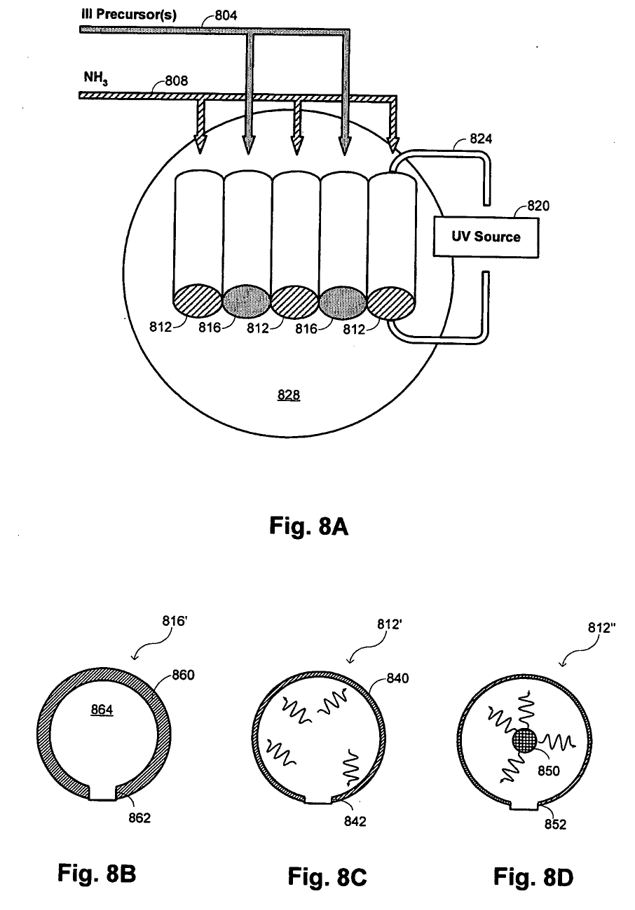

An alternative showerhead arrangement that may be used in embodiments of the invention is illustrated in FIGS. 8A-8D. A schematic overview of the structure is provided in FIG. 8A to show that the showerhead comprises an array of concentric tubes, with FIGS. 8B-8D showing specific concentric structures that may be used for different ones of the tubes. As illustrated with the top view of FIG. 8A, the array of concentric tubes is disposed above a substrate 828 and includes first tubes 812 through which flows of NH₃ 808 are provided and second tubes 816 through which flows of the group-III precursor(s) 804 are provided. The tubes are disposed along their lengths generally parallel with a surface of the substrate and include holes along the bottom (not shown in FIG. 8A) to inject gases towards the substrate. The interior of at least some of the first tubes 812 is illuminated with ultraviolet light from an ultraviolet source 820 to promote activation of the NH₃. Light may be coupled into the first tubes 812 using any suitable mechanism, one of which includes the use of one or more optical lightguides 824.

A structure that may be used for each of the second tubes 816 is shown in cross section in FIG. 8B. In this embodiment, the second tube 816′ comprises inner and outer channels 864 and 860, with flows of the group-III precursor(s) 804 being provided through the inner channel 864. A coolant such as water may be provided in the outer channel 860 to cool the group-III precursor stream through the second tube 816′. The group-III precursor is injected into the processing chamber through the hole 862 along the bottom of the tube 816′.

Examples of structures that may be used for the first tubes 812 are shown in cross section in FIGS. 8C and 8D. The tube 812′ shown in FIG. 8C includes an interior coating of an ultraviolet reflective film 840 such as may be provided with a refractory- or other-metal layer or with a dielectric stack reflector. In addition, the inner surface of the tube 812′ may be roughened to promote scattering of the ultraviolet light. Injection of NH₃ into the processing chamber may be through the hole 842 along the bottom of the tube 812′. The tube 812″ shown in FIG. 8D comprises an optical fiber lightguide 850 that runs along its length and may correspond to lightguide 824 shown in FIG. 8A. A surface of the lightguide 850 may be roughened to promote scattering of the ultraviolet light along its length. NH₃ may be injected into the processing chamber through the hole 852 along the bottom of the tube 812″. While not shown explicitly in FIGS. 8C and 8D, there may be instances in which the NF₃ streams are cooled in a manner similar to the cooling provided of the group-III precursor streams but this is not always required. In such embodiments, an outer channel may be provided on one or more of the first tubes 812 within which a coolant like water is flowed to cool the NH₃.

Having fully described several embodiments of the present invention, many other equivalent or alternative methods of producing the cladding layers of the present invention will be apparent to those of skill in the art. These alternatives and equivalents are intended to be included within the scope of the invention, as defined by the following claims.

What is claimed is:

1. A system for fabricating a compound nitride semiconductor structure, the system comprising:
a housing defining a processing chamber;
a substrate holder disposed within the processing chamber;
an NH₃ source;
a group-III precursor source;
an ultraviolet light source; and
a CVD showerhead disposed over the substrate holder, the CVD showerhead comprising:
a first plenum fluidicly coupled with the NH₃ source and having a plurality of first channels fluidicly coupled with an interior of the processing chamber, and the first plenum optically coupled with the ultraviolet light source at an ultraviolet wavelength to receive light transmitted by the ultraviolet light source within the first plenum; and
a second plenum fluidicly coupled with the group-III precursor source and having a plurality of second channels fluidicly coupled with the interior of the processing chamber.

2. The system recited in claim 1 wherein:
the ultraviolet wavelength is an NH₃ absorption wavelength; and
the ultraviolet light source comprises a substantially monochromatic light source having a wavelength substantially equal to the ultraviolet wavelength.

3. The system recited in claim 1 wherein:
the ultraviolet wavelength is an NH₃ absorption wavelength; and
the ultraviolet light source transmits light over a wavelength band that includes the ultraviolet wavelength.

4. The system recited in claim 1 wherein the group-Ill precursor source comprises a gallium precursor source.

5. The system recited in claim 1 wherein the group-III precursor source comprises precursors for a plurality of distinct group-III elements.

6. The system recited in claim 1 wherein:
the first plenum comprises a window transmissive at the ultraviolet wavelength; and
the ultraviolet light source is disposed relative to the window to transmit light into the first plenum.

7. The system recited in claim 6 wherein the window comprises quartz or sapphire.

8. The system recited in claim 1 further comprising an optical conduit transmissive at the ultraviolet wavelength, the optical conduit traversing at least a portion of the first plenum and optically coupled with the ultraviolet light source to couple light from the ultraviolet light source into the first plenum.

9. The system recited in claim 8 wherein the optical conduit comprises quartz or sapphire.

10. The system recited in claim 8 wherein the optical conduit has a roughened outer surface.

11. The system recited in claim 8 wherein the optical conduit comprises a plurality of optical fibers.

12. A system for fabricating a compound nitride semiconductor structure, the system comprising:
a housing defining a processing chamber;
a substrate holder disposed within the processing chamber;
an NH₃ source;
a group-III precursor source;
an ultraviolet light source;
a CVD showerhead disposed over the substrate holder, the CVD showerhead comprising:
a first plenum fluidicly coupled with the NH₃ source and having a plurality of first channels fluidicly coupled with an interior of the processing chamber; and
a second plenum fluidicly coupled with the group-Ill precursor source and having a plurality of second channels fluidicly coupled with the interior of the processing chamber; and
an optical conduit optically coupled with the ultraviolet light source and traversing through the CVD showerhead to transmit light from the ultraviolet light source onto a surface of a substrate disposed over the substrate holder.

13. The system recited in claim 12 wherein:
the ultraviolet wavelength is an NH₃ absorption wavelength; and
the ultraviolet light source comprises a substantially monochromatic light source having a wavelength substantially equal to the ultraviolet wavelength.

14. The system recited in claim 12 wherein:
the ultraviolet wavelength is an NH₃ absorption wavelength; and
the ultraviolet light source transmits light over a wavelength band that includes the ultraviolet wavelength.

15. The system recited in claim 12 wherein the group-III precursor source comprises a gallium precursor source.

16. The system recited in claim 12 wherein the group-Ill precursor source comprises precursors for a plurality of distinct group-III elements.

17. The system recited in claim 12 wherein the optical conduit comprises quartz or sapphire.

18. The system recited in claim 12 wherein the optical conduit comprises a plurality of optical fibers, each optical fiber being optically coupled with the ultraviolet light source and traversing through the CVD showerhead to transmit light from the ultraviolet light source onto the surface of the substrate.

19. The system recited in claim 18 wherein at least one of the optical fibers passes through one of the first channels.

20. The system recited in claim 18 wherein at least one of the optical fibers passes through one of the second channels.

21. A system for fabricating a compound nitride semiconductor structure, the system comprising:
a housing defining a processing chamber;
a substrate holder disposed within the processing chamber;
an NH₃ source;
a group-III precursor source;
an ultraviolet light source; and
a CVD showerhead disposed over the substrate holder, the CVD showerhead comprising:
a first plurality of tubes, each of the first plurality of tubes having substantially concentric inner and outer channels, the inner channel being fluidicly coupled with the group-III precursor source and the outer channel being adapted for carrying a coolant flow; and
a second plurality of tubes, each of the second plurality of tubes being fluidicly coupled with the NH₃ source and being optically coupled with the ultraviolet source.

22. The system recited in claim 21 wherein the coolant flow comprises a water flow.

23. The system recited in claim 21 wherein an interior surface of at least one of the second plurality of tubes is roughened.

24. The system recited in claim 21 wherein an interior surface of at least one of the second plurality of tubes comprises an ultraviolet reflective coating.

25. The system recited in claim 21 wherein at least one of the second plurality of tubes comprises an optical lightguide optically coupled with the ultraviolet light source and disposed within an interior of the at least one of the second plurality of tubes.

26. A system for fabricating a compound nitride semiconductor structure, the system comprising:
a housing defining a processing chamber;
a substrate holder disposed within the processing chamber;
an NH₃ source;
a group-III precursor source; and
a crossflow channel comprising a material transmissive to an ultraviolet wavelength, the crossflow channel comprising a separation plate to define a plurality of subchannels, wherein:
a first of the subchannels is fluidicly coupled with the group-III precursor source and configured to provide a flow of a group-III precursor over a substrate disposed over the substrate holder in a direction substantially parallel to a surface of the substrate;
a second of the subchannels is fluidicly coupled with the NH₃ source and configured to provide a flow of NH₃ over the substrate in a direction substantially parallel to the surface of the substrate; and
an ultraviolet light source in optical communication with the crossflow channel and configured to transmit light at the ultraviolet wavelength through the material to activate the NH₃.

27. The system recited in claim 26 wherein the ultraviolet light source is configured to transmit light through the material at a position along the crossflow channel before termination of the separation plate into the second of the subchannels.

28. The system recited in claim 26 wherein the ultraviolet source is configured to transmit light through the material at a position along the crossflow channel after termination of the separation plate where the group-III precursor and the NH₃ mix.

29. The system recited in claim 28 wherein the position is over the substrate holder.

30. The system recited in claim 26 wherein the separation plate comprises an ultraviolet reflective coating on a side defining the second of the subchannels.
